(19) United States
(12) Patent Application Publication
(10) Pub. No.: US 2026/0344294 A1
(43) Pub. Date: Oct. 29, 2026

(54) Magnetoresistive sensor

(71) Applicant: Vanguard International Semiconductor Corporation, Hsinchu (TW)

(72) Inventors: Cheng-Ping Chang, Hualien County (TW); Yung-Hsiang Chen, Hsinchu City (TW); Chien-Hsun Wu, Hsinchu City (TW); Hsing-Chao Liu, Hsinchu County (TW)

(73) Assignee: Vanguard International Semiconductor Corporation, Hsinchu (TW)

(21) Appl. No.: 19/274,665

(22) Filed: Jul. 21, 2025

(30) Foreign Application Priority Data
Apr. 25, 2025 (TW) 114115701

(51) Int. Cl. H10N 50/10; H10N 50/01; H10N 50/80

(52) U.S. Cl. CPC H10N 50/10; H10N 50/01; H10N 50/80

(57) ABSTRACT

A semiconductor device includes a substrate, an interlayer dielectric layer, an upper interconnect, a top dielectric layer, a groove, at least one through-hole via, a conductive cap layer, and a magnetoresistor. The upper interconnect is disposed on the interlayer dielectric layer and the substrate. The top dielectric layer is disposed over the upper interconnect. The groove is formed in the top dielectric layer and includes an inclined sidewall. The through-hole via is formed in the top dielectric layer and is laterally separated from the groove. The through-hole via is electrically connected to the upper interconnect, and a top surface of the through-hole via is higher than a bottom surface of the groove. The conductive cap layer covers the top surface of the through-hole via and is electrically connected thereto. The magnetoresistor is disposed on the inclined sidewall and is electrically connected to the conductive cap layer.

### CROSS REFERENCE TO RELATED APPLICATION

The present application claims the priority benefit of Taiwan patent application number 114115701, filed on Apr. 25, 2025, the disclosure of which is incorporated by reference herein in its entirety.

### BACKGROUND OF THE INVENTION

### 1. Field of the Invention

The disclosure relates to a semiconductor device, and more particularly to a semiconductor device with a magnetoresistive sensor.

### 2. Description of the Prior Art

The electronic compass capable of detecting geomagnetic direction is gaining increasing attentions as the portable electronic devices become popular. When the electronic compass is applied to the portable electronic device of limited volume (smartphones for instance), the design requirements include not only miniaturization but also the capability to sense the three-axis directional magnetic field. Based on this demand, the magnetoresistive sensors with the capability to sense the three-axis directional magnetic field are therefore widely used in various kinds of the electronic devices.

However, due to structural and manufacturing process limitations, current magnetic sensing devices still need further improvement.

### SUMMARY OF THE INVENTION

According to one embodiment of the disclosure, a semiconductor device is provided, comprising: a substrate, an inter-layer dielectric layer, an upper interconnect, a top dielectric layer, a groove, at least one through-hole via, a conductive cap layer, and a magnetoresistor. The inter-layer dielectric layer is formed on the substrate, the upper interconnect is formed on the inter-layer dielectric layer, and the top dielectric layer is formed on the upper interconnect. The groove is formed in the top dielectric layer and includes an inclined sidewall. The through-hole via is formed in the top dielectric layer and laterally separated from the groove, where the through-hole via is electrically connected to the upper interconnect, and a top surface of the through-hole via is higher than a bottom surface of the groove. The conductive cap layer covers a top surface of the through-hole via and is electrically connected to the through-hole via. The magnetoresistor is formed on the inclined sidewall and is electrically connected to the conductive cap layer.

According to another embodiment of the disclosure, a manufacturing method of a semiconductor device is provided, comprising the steps of: providing a substrate; forming an upper interconnect on the substrate; forming a top dielectric layer on the upper interconnect; forming at least one through-hole via in the top dielectric layer, where the through-hole via is electrically connected to the upper interconnect; forming a conductive cap layer to cover the through-hole via; after forming the conductive cap layer, etching the top dielectric layer to form a groove, where the groove includes an inclined sidewall and is laterally separated from the through-hole via; forming a magnetoresistor on the inclined sidewall.

The translation maintains the specific technical terminology and precisely captures the structural and manufacturing process details of the semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a semiconductor device according to one embodiment of the disclosure.

FIG. 2 is a partially enlarged schematic top view of a semiconductor device, including a through-hole via and an upper interconnect, according to some embodiments of the disclosure.

FIGS. 3A to 3B are partially enlarged schematic top views of a semiconductor device according to some embodiments of the disclosure, including a through-hole via and a conductive cap layer.

FIGS. 4 to 8 are schematic cross-sectional views of different stages in the manufacturing method of a semiconductor device according to one embodiment of the disclosure.

FIG. 9 is a flowchart of the manufacturing method for a semiconductor device according one embodiment of the disclosure.

### DETAILED DESCRIPTION

The disclosure provides several different embodiments that can be used to implement various features of the disclosure. For the sake of simplification, the disclosure also describes examples of specific components and arrangements. The purpose of providing these embodiments is merely for illustration, not for limitation. For instance, the statement “a first component formed on or above a second component” may refer to “the first component directly contacts the second component” or may refer to “other components exist between the first and second components” such that they do not directly contact each other. Additionally, various embodiments in the disclosure may use repeated component symbols and/or text annotations. The use of these repeated component symbols and text annotations is to make the description more concise and clear, not to indicate relationships between different embodiments and/or configurations.

Furthermore, regarding spatial-related descriptive terms mentioned in the disclosure, such as “below”, “above”, “low”, “high”, “downward”, “upward”, “underneath”, “on top of”, “bottom”, “top”, and similar terms, for ease of description, their usage is to describe the relative relationship between one component or feature and another (or multiple) components or features in the drawings. Beyond the orientation shown in the drawings, these spatial-related terms are also used to describe possible orientations during the manufacturing, use, and operation of semiconductor devices. For example, when a semiconductor device is rotated 180 degrees, a component originally disposed “above” other components may become disposed “below” other components. Therefore, as the orientation of the semiconductor device changes (rotated 90 degrees or other angles), the spatial-related descriptions should be interpreted correspondingly.

Although the disclosure uses terms like first, second, third, etc., to describe various components, parts, regions, layers, and/or sections, it should be understood that these components, parts, regions, layers, and/or sections should not be limited by such terms. These terms are merely used to distinguish one component, part, region, layer, and/or section from another, and do not inherently imply or represent any prior sequence, nor do they represent the arrangement order or manufacturing sequence of components. Therefore, within the scope of the specific embodiments of the disclosure, the first component, part, region, layer, or section discussed below may also be referred to as the second component, part, region, layer, or section.

The terms “about” or “substantially” in the disclosure typically indicate within 20% of a given value or range, preferably within 10%, and more preferably within 5%, or 3%, or 2%, or 1%, or 0.5%. It should be noted that the quantities provided in the description are approximate quantities, and even without specific mention of “about” or “substantially”, such meaning can be implied.

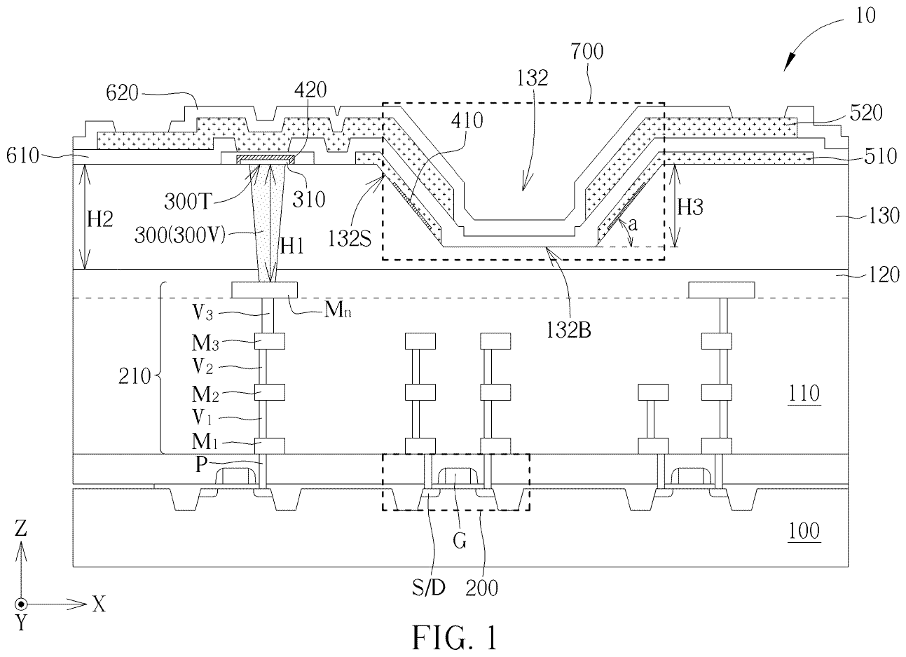

FIG. 1 is a schematic cross-sectional view of a semiconductor device 10 according to one embodiment of the disclosure. As shown in FIG. 1, the semiconductor device 10, such as a three-axis magnetoresistive sensor, includes a substrate 100, an inter-layer dielectric layer 110, an upper interconnect Mₙ, a top dielectric layer 130, a groove 132, at least one through-hole via 300, a conductive cap layer 310, and a magnetoresistor 410. According to one embodiment, the semiconductor device 10 includes an active device 200 and a magnetoresistive sensor 700, which can be electrically connected through the through-hole via 300. The active device 200 can be part of a signal processing circuit (including logic and analog circuits), allowing electrical signals from the magnetoresistive sensor 700 to be received and processed by the signal processing circuit.

The substrate 100 can be a silicon substrate, a silicon-germanium (SiGe) substrate, a bulk semiconductor substrate, a compound semiconductor substrate, a silicon-on-insulator (SOI) substrate, or similar substrates.

In one embodiment, at least one active device 200 (such as a transistor device) and a passive device (not shown) may be disposed between the substrate 100 and the top dielectric layer 130 (e.g., between the substrate 100 and the inter-layer dielectric layer 110). For example, the active device 200 is a field-effect transistor (FET) including a gate structure G and source/drain regions S/D.

The inter-layer dielectric layer 110 is disposed on the substrate 100 and covers the active device 200, which protects the active device 200 and prevents leakage or direct electrical connection between layers. A conductive contact structure P electrically connected to the active device 200 is also formed in the inter-layer dielectric layer 110. In some embodiments, the material of the inter-layer dielectric layer 110 may include phosphosilicate glass (PSG), borophosphosilicate glass (BPSG), undoped silicate glass (USG), fluorinated silicate glass (FSG), similar materials, multiple layer structures thereof, or combinations thereof.

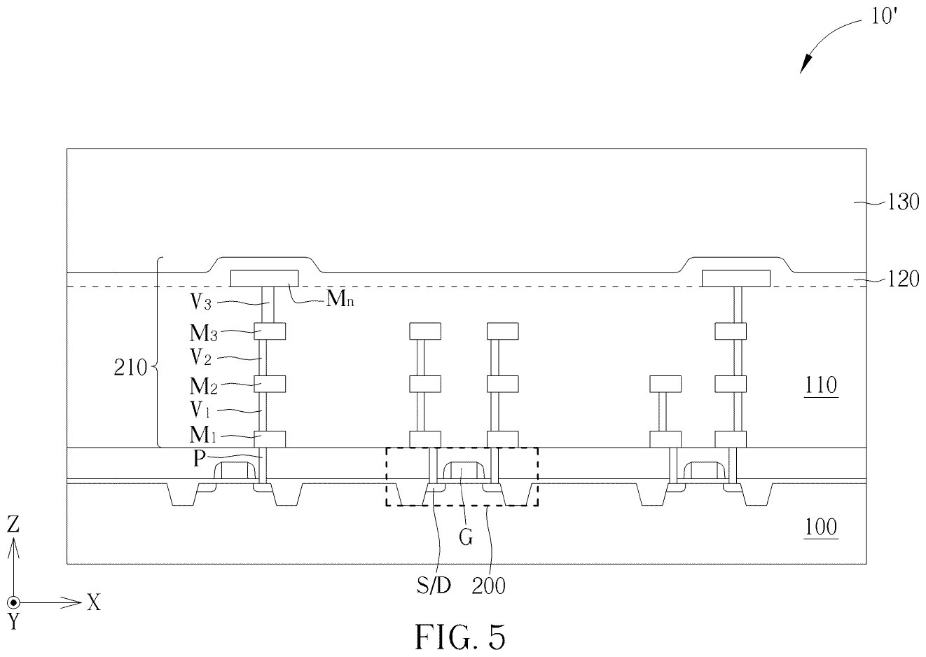

In some embodiments, the interconnect structure 210 can be formed in the inter-layer dielectric layer 110 and is used to connect active devices 200 on the substrate 100 and other components or external circuits through the conductive contact structure P. The interconnect structure 210 includes metal stack and at least one via, for example, the metal stack may include multiple intermediate metal layers M₁, M₂, M₃, and a top metal layer (also called an upper interconnect Mₙ), and at least one via may include multiple vias V₁, V₂, V₃. The number of the intermediate metal layers M₁, M₂, M₃, and vias V₁, V₂, V₃ is not limited to 3 layers and can be further increased, so the layer number of the upper interconnect Mₙ (i.e., n value) is not limited to 4 but can be any integer greater than 3. The intermediate metal layers M₁, M₂, M₃, and upper interconnect Mₙ in the interconnect structure 210 can be electrically connected to corresponding vias V₁, V₂, V₃. In some embodiments, the material of the intermediate metal layers M₁, M₂, M₃, upper interconnect Mₙ, and the vias V₁, V₂, V₃ may include conductive materials such as tungsten (W), nickel (Ni), titanium (Ti), tantalum (Ta), aluminum (Al), copper (Cu), titanium nitride (TiN), tantalum nitride (TaN), or alloys, stacks, or combinations thereof. According to one embodiment, the material of the intermediate metal layers M₁, M₂, M₃, and the upper interconnect Mₙ includes aluminum-copper alloy (AlCu), while the material of the vias V₁, V₂, V₃ includes tungsten (W). In one embodiment, the semiconductor device 10 can further include a dielectric cap layer 120. The dielectric cap layer 120 is disposed between the inter-layer dielectric layer 110 and the top dielectric layer 130, and directly contacts the inter-layer dielectric layer 110 and the upper interconnect Mₙ. A top surface of the dielectric cap layer 120 can be either flat or non-flat. According to one embodiment of the disclosure, the dielectric cap layer 120 can also have a non-flat top surface, similar to the structure shown in FIG. 5. As shown in FIG. 5, when the dielectric cap layer 120 has a non-flat top surface, a portion of the dielectric cap layer 120 will cover the upper interconnect Mₙ, and the height of the top surface of the dielectric cap layer 120 covering the upper interconnect Mₙ will be higher than the height of the top surface of the other portions of the dielectric cap layer 120. The material of the dielectric cap layer 120 can be the same as the inter-layer dielectric layer 110, which will not be repeated here. Since the material of the dielectric cap layer 120 can be the same as the inter-layer dielectric layer 110, after forming the semiconductor device 10, there may not be a clear layer separation between the dielectric cap layer 120 and the inter-layer dielectric layer 110.

The top dielectric layer 130 is disposed on the upper interconnect Mₙ, used for electrical isolation of component structures above it from the active structures and interconnect structures 210 below. The material of the top dielectric layer 130 can be the same as or different from the material of the inter-layer dielectric layer 110.

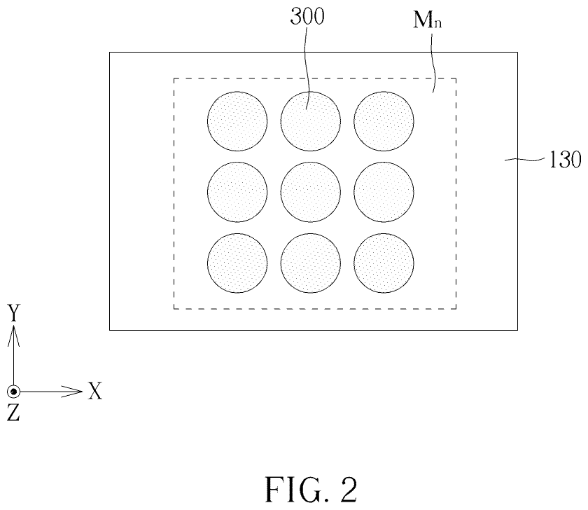

The through-hole via 300 is formed in the top dielectric layer 130 to electrically connect the upper interconnect Mₙ below the through-hole via 300 and the conductive connection line 510 above the top dielectric layer 130. The through-hole via 300 is disposed above the active device 200 and electrically connected to the active device 200 through the interconnect structure 210, where the through-hole via 300 need not be directly above the active device 200, depending on the design requirements of the semiconductor device 10. A maximum depth H1 of the through-hole via 300 is greater than a thickness H2 of the top dielectric layer 130. Specifically, the upper interconnect Mₙ is located below the top dielectric layer 130, so the through-hole via 300 penetrates from a top surface of the top dielectric layer 130 through the top dielectric layer 130 and the dielectric cap layer 120 to a top surface of the upper interconnect Mₙ, so that the maximum depth H1 of the through-hole via 300 is greater than the thickness H2 of the top dielectric layer 130. In one embodiment, the aspect ratio of the through-hole via 300 is greater than 2.5, for example, with a depth of 6 micrometers (μm) and a width of 2 micrometers (μm), giving the through-hole via 300 a vertical and narrow profile. In one embodiment, multiple through-hole vias 300 can be formed in the top dielectric layer 130 to electrically connect to the same upper interconnect Mₙ, with a structure as shown in the schematic top view of FIG. 2. Referring to FIG. 2, multiple through-hole vias 300 are disposed corresponding to the upper interconnect Mₙ, and the overall projection area of the multiple through-hole vias 300 is smaller than the projection area of the upper interconnect Mₙ. By electrically connecting the upper interconnect Mₙ with multiple through-hole vias 300, the contact region between the upper interconnect Mₙ and the conductive connection line 510 may have lower resistance or be capable of carrying higher current. The through-hole via 300 can be filled with conductive materials such as tungsten (W), nickel (Ni), titanium (Ti), tantalum (Ta), aluminum (Al), copper (Cu), titanium nitride (TiN), tantalum nitride (TaN), or stacks or combinations thereof. In one embodiment, the through-hole via 300 is filled with tungsten.

The conductive cap layer 310 is disposed on the top surface 300T of the through-hole via 300 and electrically connected to the through-hole via 300. The conductive cap layer 310 can be used to protect the through-hole via 300. Specifically, after forming the through-hole via 300, its top surface 300T is directly exposed from the top dielectric layer 130. During subsequent photolithography and etching processes (such as wet etching) to form the groove 132 in the top dielectric layer 130, the top surface 300T of the through-hole via 300 may be adversely affected, resulting in the changes in properties such as oxidation or erosion, which increases the overall resistance of the through-hole via 300. Therefore, a conductive cap layer 310 needs to be disposed on the top surface 300T of the through-hole via 300 for protection. An area of the conductive cap layer 310 can be larger than a top surface area of the through-hole via 300. Thus, in addition to completely covering the top surface 300T of the through-hole via 300, the top surface of the top dielectric layer 130 adjacent to the through-hole via 300 can also be covered by the conductive cap layer 310 to further ensure that the through-hole via 300 will not be damaged by subsequent etching processes. The shape of the conductive cap layer 310 can be any suitable shape, such as circular or square, depending on actual requirements. The material of the conductive cap layer 310 can include gold (Au), platinum (Pt), palladium (Pd), nickel (Ni), titanium (Ti), tantalum (Ta), or titanium nitride (TiN). These materials are resistant to acids, bases, and oxidations, and have low resistivity. For example, the contact resistance of the conductive cap layer 310 can be lower than the resistance of the through-hole via 300, but is not limited thereto. According to one embodiment, the contact resistance of the conductive cap layer 310 may also be higher than the resistance of the through-hole via 300. In one embodiment, the conductive cap layer 310 is only used to protect the top surface 300T of the through-hole via 300, and the contact resistance of the conductive cap layer 310 is smaller than the contact resistance of the through-hole via 300.

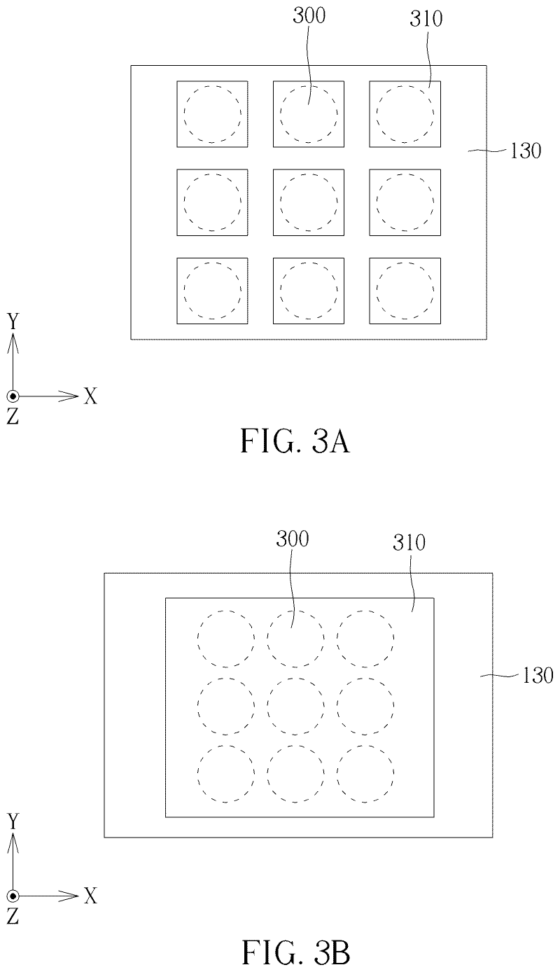

According to one embodiment, the through-hole via 300 and the conductive cap layer 310 can have a one-to-one or many-to-one configuration. FIGS. 3A and 3B are partially enlarged schematic top views of a semiconductor device including through-hole vias 300 and conductive cap layers 310 according to some embodiments of the disclosure. In one embodiment, as shown in FIG. 3A, the through-hole via 300 and the conductive cap layer 310 have a one-to-one configuration, so the top surface of each through-hole via 300 can be covered by the corresponding conductive cap layer 310. In another embodiment, as shown in FIG. 3B, the through-hole via 300 and the conductive cap layer 310 have a many-to-one configuration relationship, so multiple through-hole vias 300 can be covered by a single conductive cap layer 310.

Referring again to FIG. 1, the groove 132 is formed in the top dielectric layer 130 and laterally separated from the through-hole via 300. The maximum depth H3 of the groove 132 can be less than the thickness of the top dielectric layer 130; in other words, the groove 132 does not penetrate through the top dielectric layer 130. Therefore, the maximum depth H3 of the groove 132 is less than the maximum depth H1 of the through-hole via 300, and the bottom surface 132B of the groove 132 is lower than the top surface 300T of the through-hole via 300. The groove 132 includes an inclined sidewall 132S, such that the width of the top opening of the groove 132 is larger than the width of its bottom surface 132B.

Referring again to FIG. 1, the magnetoresistor 410 is formed on the top dielectric layer 130 and located on the inclined sidewall 132S of the groove 132. When the semiconductor device 10 is located in the environment with magnetic field, the resistance of the magnetoresistor 410 can vary accordingly with the magnetic field. Therefore, the semiconductor device 10 may generate a corresponding sensing electrical signal. The inclined sidewall 132S of the groove 132 can be provided with the magnetoresistor 410. Each magnetoresistor 410 is laterally separated in the X direction and continuously extends on the inclined sidewall 132S along the Y direction. In the cross-sectional view of FIG. 1, although the magnetoresistors 410 are laterally separated in the X direction, they can be electrically connected, for example, by the conductive connection lines 510 that electrically connect the ends (not shown) of the magnetoresistors 410. According to one embodiment, the semiconductor device 10 can include multiple grooves 132, with the magnetoresistors 410 disposed on the inclined sidewalls 132S of each groove 132.

The magnetoresistors 410 formed on the inclined sidewall 132S of the groove 132 can be electrically connected to each other to form a Wheatstone bridge configuration. Therefore, when the ambient magnetic field of the semiconductor device 10 changes, the resistance of each magnetoresistor 410 may vary correspondingly. If a voltage is applied to the Wheatstone bridge, an output voltage can be obtained. The ambient magnetic field can be determined by analyzing this output voltage. When the semiconductor device 10 is used to sense the magnitude and direction of the magnetic field in its environment, such as detecting the Earth's magnetic field, it needs to simultaneously detect horizontal and vertical components of the magnetic field. Therefore, the inclined sidewall 132S can have an inclination angle a, allowing the magnetoresistor 410 formed on the inclined sidewall 132S to effectively detect and calculate the components of the Earth's magnetic field and determine its direction. The material of the magnetoresistor 410 may include nickel-iron (NiFe), cobalt-iron (CoFe), cobalt-iron-boron (CoFeB), multilayers or combinations of the foregoing materials, or other suitable stacked structures for anisotropic magnetoresistor (AMR) or giant magnetoresistor (GMR). The material of the magnetoresistor 410 can additionally include copper (Cu), platinum-manganese (PtMn), iridium-manganese (IrMn), ruthenium (Ru). In one embodiment, the magnetoresistor 410 can be an anisotropic magnetoresistor.

In one embodiment, the magnetoresistor 410 can be electrically connected to the active device 200 via the conductive connection line 510. For example, the conductive connection line 510 can be formed on the top dielectric layer 130 and the inclined sidewall 132S of the groove 132, where the conductive connection line 510 can connect to each of the magnetoresistors 410, the conductive cap layer 310 on the top surface 300T of the through-hole via 300, and the bonding pad layer 520 for external connection. As shown in FIG. 1, conductive connection line 510 is located on the magnetoresistor 410 and the through-hole via 300, and these conductive connection line 510 can be electrically connected at some point in the semiconductor device 10, allowing the electrical signal generated by the magnetoresistor 410 to be transmitted via the conductive connection line 510 to the through-hole via 300, and then to the active device 200 electrically connected to the through-hole via 300. In another embodiment, the resistance of the through-hole via 300 or the resistance of the conductive cap layer 310 on the top surface 300T of the through-hole via 300 is lower than the resistance of the magnetoresistor 410.

In one embodiment, the semiconductor device 10 further includes a patterned magnetoresistive layer 420 covering the top surface and the side surface of the conductive cap layer 310. Specifically, when forming the magnetoresistive layers, the magnetoresistor 410 and the patterned magnetoresistive layer 420 can be formed on the inclined sidewall 132S of the groove 132 and on the conductive cap layer 310 of the through-hole via 300, respectively, with the magnetoresistor 410 being laterally separated from the patterned magnetoresistive layer 420. The material of the patterned magnetoresistive layer 420 can be the same as the magnetoresistor 410, and will not be repeated here. By covering the top surface and side surface of the conductive cap layer 310 with the patterned magnetoresistive layer 420, the top surface 300T of the through-hole via 300 can be further protected from erosion or oxidation during subsequent processes. In one embodiment, since the semiconductor device 10 is equipped with a conductive connection line 510 to electrically connect the magnetoresistor 410 and the through-hole via 300, the patterned magnetoresistive layer 420 located on the top surface 300T of the through-hole via 300 is also electrically connected with the magnetoresistor 410.

The first passivation layer 610 is disposed on the top dielectric layer 130 and covers the top dielectric layer 130 and the magnetoresistor 410. The first passivation layer 610 is used to protect the top dielectric layer 130, the conductive connection line 510, the magnetoresistor 410, and the patterned magnetoresistive layer 420, and has an electrical isolation effect. In some embodiments, depending on different design requirements, a bonding pad layer 520 and a second passivation layer 620 can be further disposed on the first passivation layer 610, where the bonding pad layer 520 can be used to form redistribution layer (RDL) and set\reset coil, allowing the semiconductor device 10 to be electrically connected to external circuits via bonds.

The semiconductor device 10 of this disclosure is not limited to the structure shown in FIG. 1. According to one embodiment, the top dielectric layer 130 may include multiple parallel grooves 132, not limited to a single groove 132. According to one embodiment, the interconnect structure 210 and the active device 200 can be laterally separated from the groove 132 respectively, and are not limited to being disposed directly below the groove 132. According to one embodiment, the bonding pad layer 520 can be laterally separated from the magnetoresistor 410 and the through-hole via 300, and are not limited to being disposed directly above the magnetoresistor 410 and the through-hole via 300.

To enable those skilled in the art to implement the invention described in this disclosure, the manufacturing method of the semiconductor device 10 will be further specifically described below.

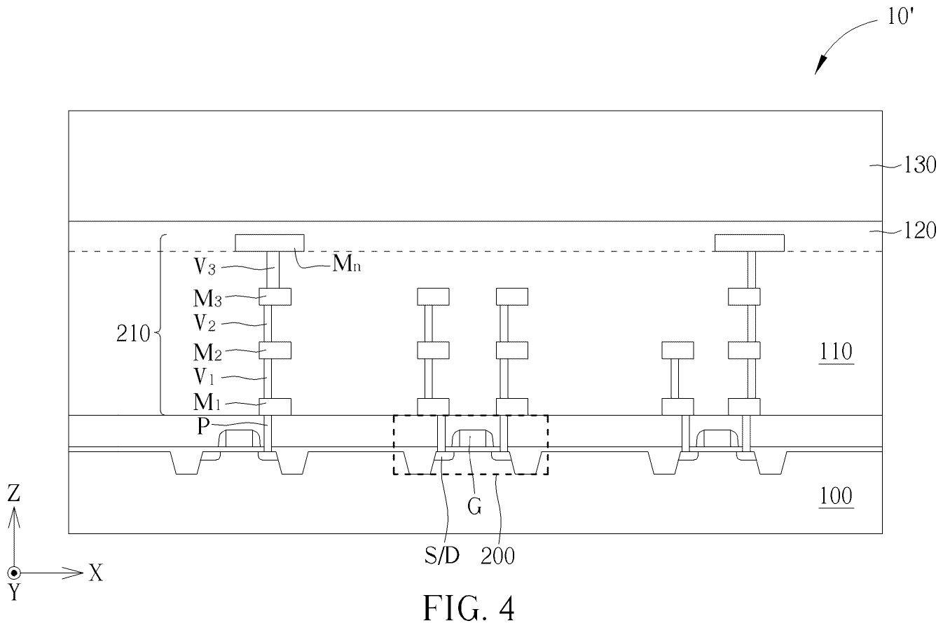

FIGS. 4 to 8 are cross-sectional views of different stages in the manufacturing method of the semiconductor device 10 according to some embodiments of the disclosure. Referring to FIG. 4, the semiconductor structure 10′ formed at this manufacturing stage includes at least a substrate 100, at least one active device 200, at least one interconnect structure 210, an inter-layer dielectric layer 110, an upper interconnect Mₙ, a dielectric cap layer 120, and a top dielectric layer 130. The materials of the substrate 100, interconnect structure 210, inter-layer dielectric layer 110, upper interconnect Mₙ, and dielectric cap layer 120 have been explained in previous paragraphs and will not be repeated here. The inter-layer dielectric layer 110 is formed on the substrate 100. The inter-layer dielectric layer 110 can be formed by stacking multiple sub-dielectric layers (not shown), with the formation method being chemical vapor deposition (CVD), such as high-density plasma CVD (HDP-CVD), and metal deposition processes can be performed between sub-dielectric layers to form intermediate metal layers M₁, M₂-Mₙ₋₁ of the interconnect structure 210. Subsequently, photolithography and etching processes can be performed to form holes in each sub-dielectric layer, where these holes can penetrate the sub-dielectric layers and expose the intermediate metal layers M₁, M₂-Mₙ₋₁, followed by metal deposition and metal planarization processes to form vias V₁, V₂-Vₙ₋₁ of the interconnect structure 210 within the holes. A conductive layer is deposited on the inter-layer dielectric layer 110, and then photolithography and etching processes are performed on this conductive layer to form the upper interconnect Mₙ on the substrate 100.

After forming the upper interconnect Mₙ, a dielectric cap layer 120 is formed on the inter-layer dielectric layer 110 and upper interconnect Mₙ, with the formation method being chemical vapor deposition, such as high-density plasma CVD (HDP-CVD), to form a dielectric layer with a density equal to or denser than the inter-layer dielectric layer 110. Subsequently, a chemical-mechanical polishing (CMP) process can be performed on the dielectric layer to planarize a top surface of the dielectric layer, thereby eliminating surface height differences and avoiding their impact on subsequent processes.

Next, the top dielectric layer 130 is formed on the upper interconnect Mₙ and dielectric cap layer 120. The process of forming the top dielectric layer 130 can include chemical vapor deposition (CVD), such as plasma-enhanced CVD (PECVD).

In one embodiment, the dielectric cap layer 120 may have a non-planar top surface and resembles the structure shown in FIG. 5. FIG. 5 is a schematic cross-sectional view of the semiconductor structure 10′ after forming the dielectric cap layer 120. As shown in FIG. 5, after forming a conformal dielectric layer, no planarization process is performed, resulting in height differences on the top surface of the dielectric cap layer 120. The embodiment in FIG. 5 is similar to the embodiment in FIG. 4, with the difference being that after forming a conformal dielectric layer (corresponding to the dielectric cap layer 120) on the inter-layer dielectric layer 110 and upper interconnect Mₙ, no planarization process is performed on the conformal dielectric layer in FIG. 5. Instead, the top dielectric layer 130 is formed on the conformal dielectric layer, causing a portion of the dielectric cap layer 120 to cover the upper interconnect Mₙ, with the top surface height of the portion covering the upper interconnect Mₙ being higher than the top surface height of other portion of the dielectric cap layer 120. Even though the dielectric cap layer 120 has height differences, a planarization process could be performed on the top dielectric layer 130, and the top surface of dielectric layer 130 can still be flat.

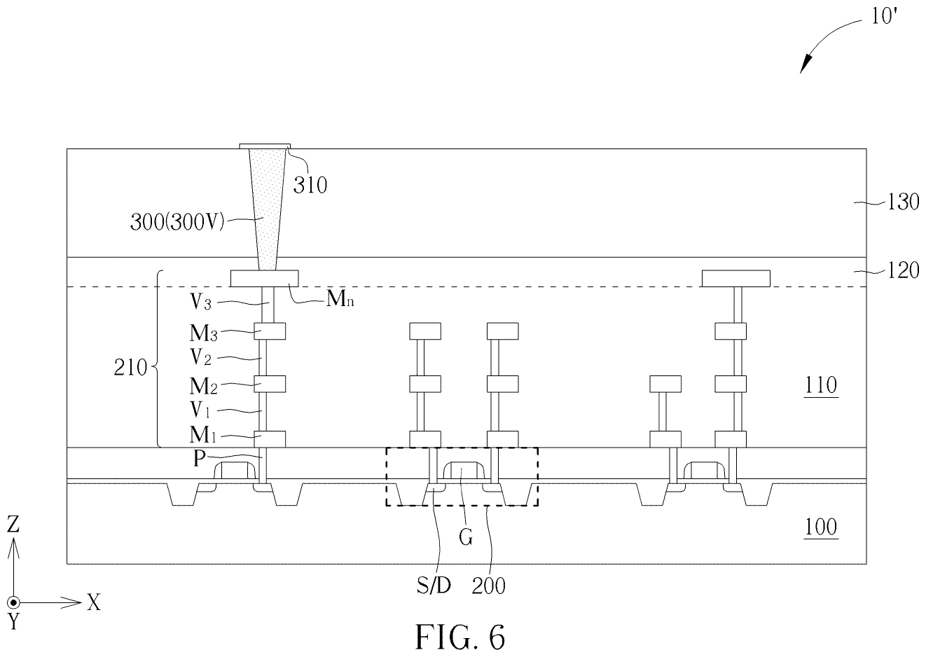

FIG. 6 is a schematic cross-sectional view of the semiconductor structure 10′ after forming the through-hole via 300 and the conductive cap layer 310. Referring to FIG. 6, a through-hole via 300 is formed in the top dielectric layer 130. The formation of the through-hole via 300 may include the following steps: first, photolithography and etching processes can be performed to form a through-hole cavity 300V in the top dielectric layer 130, exposing the upper interconnect Mₙ. Then, a deposition process is performed to fill the through-hole cavity 300V with conductive material, followed by planarization of the conductive material to expose the top dielectric layer 130.

In one embodiment, before filling the conductive material into the through-hole cavity 300V, a first deposition process can be performed, such as filling another conductive material into the through-hole cavity 300V, followed by an etch-back process to etch back the conductive material until its top surface is lower than the top surface of the top dielectric layer 130. Then, a second deposition process is performed to fill the through-hole cavity 300V with the conductive material. The conductive material used in the first deposition process can be the same as the conductive material used in the second deposition process. Compared to the through-hole 300 formed by a single deposition process, performing two conductive material deposition processes can further prevent voids from forming inside the relatively long through-hole 300V. As a result, the through-hole 300 can have a lower resistance.

According to one embodiment of the disclosure, after forming the upper interconnect Mₙ, the top surface of the upper interconnect Mₙ is exposed and etched only during the formation of the through-hole via 300, and not during the other processes. Therefore, this can prevent surface damage to the upper interconnect Mₙ caused by multiple exposures and etching, which would otherwise increase its resistance.

Referring again to FIG. 6, after forming the through-hole via 300 as described above, a conductive cap layer 310 is formed to cover the top surface 300T of the through-hole via 300. The conductive cap layer 310 can be formed, for example, by using a metal deposition process to deposit a conductive layer (not shown) on the top dielectric layer 130, followed by photolithography and etching processes to pattern the conductive layer and thereby form the conductive cap layer 310. According to one embodiment of the disclosure, the material of the conductive cap layer 310 is not a magnetoresistive material, and when forming the conductive cap layer 310, the groove 132 for accommodating the magnetoresistor 410 as shown in FIG. 1 has not yet been formed in the top dielectric layer 130.

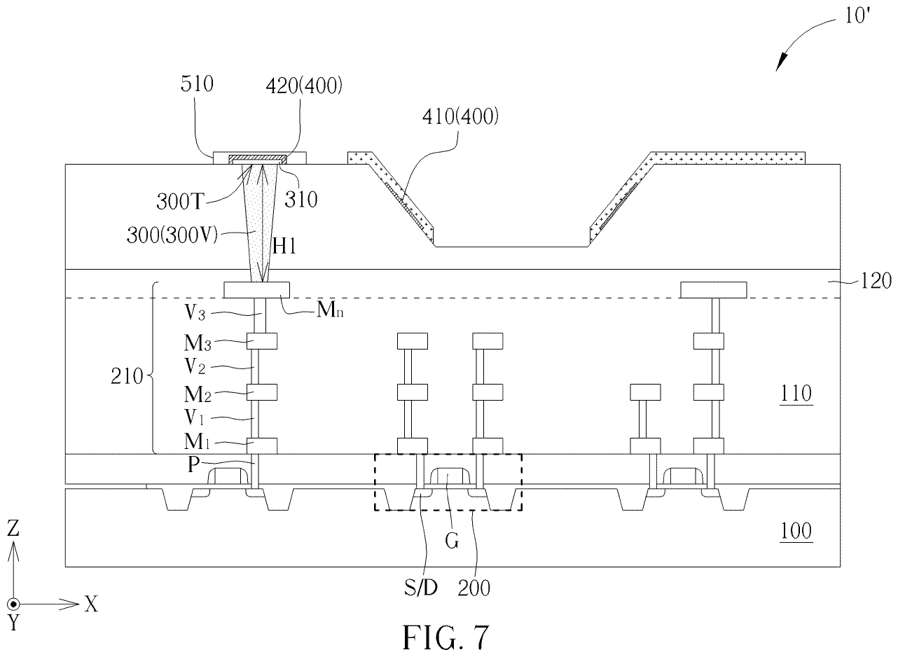

FIG. 7 is a schematic cross-sectional view of the semiconductor structure 10′ after forming the groove 132, the magnetoresistor 410, the patterned magnetoresistive layer 420, and the conductive connection line 510. After obtaining the structure shown in FIG. 6, referring to FIG. 7, a groove 132 can be formed in the top dielectric layer 130, where the groove 132 is laterally separated from the through-hole via 300. The groove 132 can be formed by the photolithography and etching process. In one embodiment, after performing the photolithography process, the patterned photoresist layer (not shown) can be baked to form a curved surface before subsequent etching. The etching process can, for example, be carried out with an etch rate ratio of 1:1 between the photoresist layer and the top dielectric layer 130, to form a groove 132 with inclined sidewall 132S.

As shown in FIG. 7, after forming the groove 132, a magnetoresistive layer 400 is formed on the top dielectric layer 130. For example, the magnetoresistive layer 400 can be deposited using physical vapor deposition (PVD). The material of the magnetoresistive layer 400 has been explained in previous paragraphs and will not be repeated here. The magnetoresistive layer 400 can be patterned to form a magnetoresistor 410 and a patterned magnetoresistive layer 420. In one embodiment, the magnetoresistive layer 400 can be patterned so that the magnetoresistor 410 is disposed on the inclined sidewall 132S of the groove 132, and the patterned magnetoresistive layer 420 covers the top surface and side surface of the conductive cap layer 310.

After forming the magnetoresistor 410, a conductive connection line 510 can be formed to cover and electrically connected to the conductive cap layer 310 and the magnetoresistor 410. Specifically, the formation of the conductive connection line 510 can be achieved by first depositing a conductive layer over the entire top dielectric layer 130, and then patterning the conductive layer to form the conductive connection line 510, but is not limited thereto. The material of the conductive connection line 510 can be the same as the upper interconnect Mₙ, with a lower resistivity than the magnetoresistive layer 400, which will not be repeated here.

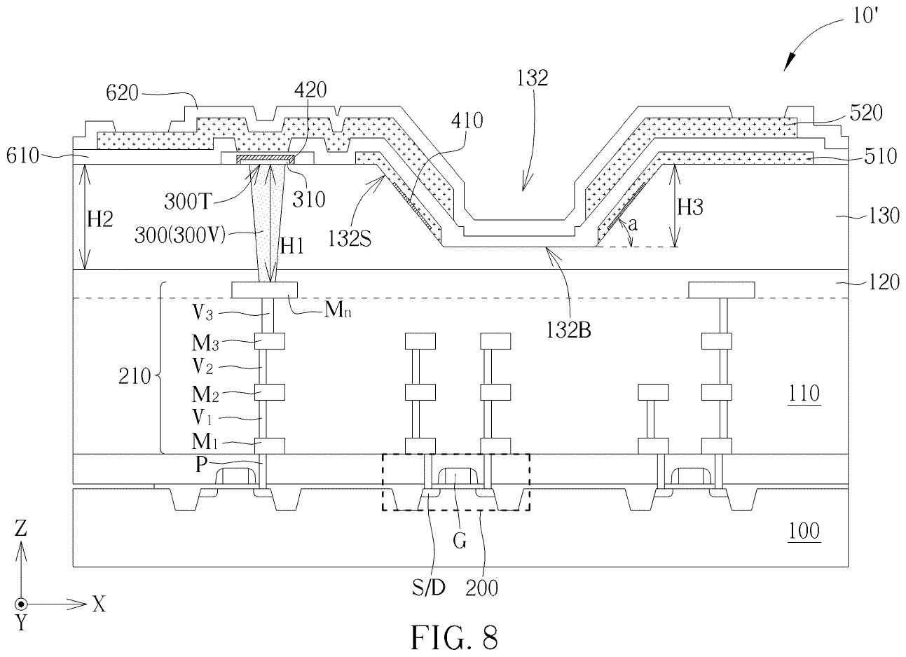

After obtaining the structure shown in FIG. 7, referring to FIG. 8, a first passivation layer 610, bonding pad layer 520, and second passivation layer 620 can be sequentially formed on the top dielectric layer 130. The material of the bonding pad layer 520 may include aluminum, nickel, gold, copper, the alloys thereof, or stacked layers thereof. The first passivation layer 610 covers the top dielectric layer 130, the magnetoresistor 410, and the patterned magnetoresistive layer 420. The material of the first passivation layer 610 and second passivation layer 620 may include silicon oxide, silicon nitride, silicon oxynitride, similar materials, or combinations thereof, and can be formed through chemical vapor deposition or plasma-enhanced chemical vapor deposition.

Finally, an opening can be formed in the second passivation layer 620 to expose a portion of the bonding pad layer 520, forming the structure shown in FIG. 1.

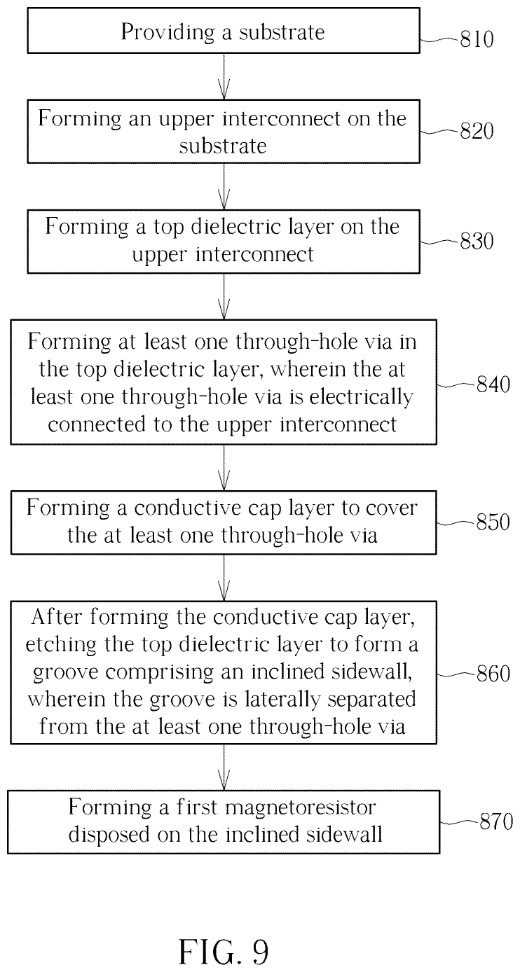

Referring to FIG. 9, the disclosure provides a method of manufacturing a semiconductor device, including the following steps. Step 810, providing a substrate; step 820, forming an upper interconnect on the substrate; step 830, forming a top dielectric layer on the upper interconnect; step 840, forming at least one through-hole via in the top dielectric layer, where the through-hole via is electrically connected to the upper interconnect; step 850, forming a conductive cap layer to cover the through-hole via; step 860, after forming the conductive cap layer, etching the top dielectric layer to form a groove, where the groove includes the inclined sidewall and is laterally separated from the through-hole via; step 870, forming a magnetoresistor on the inclined sidewall.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
an interlayer dielectric layer disposed on the substrate;
an upper interconnect disposed on the interlayer dielectric layer;
a top dielectric layer disposed on the upper interconnect;
a groove disposed in the top dielectric layer, wherein the groove comprises an inclined sidewall;
at least one through-hole via disposed in the top dielectric layer and laterally separated from the groove, wherein the at least one through-hole via is electrically connected to the upper interconnect, and a top surface of the at least one through-hole via is higher than a bottom surface of the groove;
a conductive cap layer covering the top surface of the at least one through-hole via and electrically connected to the at least one through-hole via; and
a magnetoresistor disposed on the inclined sidewall and electrically connected to the conductive cap layer.

2. The semiconductor device according to claim 1, wherein the groove comprises a maximum depth, and the maximum depth is less than a maximum depth of the at least one through-hole via.

3. The semiconductor device according to claim 1, wherein a maximum depth of the at least one through-hole via is greater than a maximum thickness of the top dielectric layer.

4. The semiconductor device according to claim 1, wherein a resistivity of the at least one through-hole via is less than a resistivity of the magnetoresistor.

5. The semiconductor device according to claim 1, wherein an aspect ratio of the at least one through-hole via is greater than 2.5.

6. The semiconductor device according to claim 1, wherein the at least one through-hole via comprises a plurality of through-hole vias, and a total projected area of the through-hole vias is less than a projected area of the upper interconnect.

7. The semiconductor device according to claim 1, wherein the conductive cap layer comprises Au, Pt, Pd, Ni, Ti, Ta, or TiN.

8. The semiconductor device according to claim 7, wherein a contact resistance of the conductive cap layer is less than a resistance of the magnetoresistor.

9. The semiconductor device according to claim 7, wherein a thickness of the conductive cap layer is less than a thickness of the upper interconnect.

10. The semiconductor device according to claim 1, further comprising a conductive connection line disposed on the top dielectric layer and the inclined sidewall, and electrically connected to the conductive cap layer and the magnetoresistor.

11. The semiconductor device according to claim 1, further comprising at least one active component disposed between the substrate and the top dielectric layer, wherein the at least one active component is electrically connected to the at least one through-hole via.

12. The semiconductor device according to claim 1, further comprising a dielectric cap layer disposed between the interlayer dielectric layer and the top dielectric layer, wherein the at least one through-hole via passes through the dielectric cap layer.

13. The semiconductor device according to claim 12, wherein a portion of the dielectric cap layer covers the upper interconnect, and a height of the portion of the dielectric cap layer covering the upper interconnect is greater than a height of another portion of the dielectric cap layer.

14. A method for manufacturing a semiconductor device, comprising:
providing a substrate;
forming an upper interconnect on the substrate;
forming a top dielectric layer on the upper interconnect;
forming at least one through-hole via in the top dielectric layer, wherein the at least one through-hole via is electrically connected to the upper interconnect;
forming a conductive cap layer to cover the at least one through-hole via;
after forming the conductive cap layer, etching the top dielectric layer to form a groove comprising an inclined sidewall, wherein the groove is laterally separated from the at least one through-hole via; and
forming a magnetoresistor disposed on the inclined sidewall.

15. The manufacturing method according to claim 14, further comprising:
before forming the at least one through-hole via, performing a planarization process on the top dielectric layer.

16. The manufacturing method according to claim 14, wherein forming the at least one through-hole via in the top dielectric layer comprises:
etching the top dielectric layer to form a through-hole;
filling a conductive material into the at least one through-hole; and
planarizing the conductive material until the top dielectric layer is exposed.

17. The manufacturing method according to claim 16, wherein a resistance of the conductive material is less than a resistance of the magnetoresistor.

18. The manufacturing method according to claim 16, wherein, before filling the conductive material into the at least one through-hole, the method further comprises:
filling another conductive material into the at least one through-hole; and
etching back the another conductive material until a top surface of the another conductive material is lower than a top surface of the top dielectric layer.

19. The manufacturing method according to claim 14, wherein a thickness of the conductive cap layer is less than a thickness of the upper interconnect.

20. The manufacturing method according to claim 14, wherein, after forming the groove, the method further comprises:
forming a magnetoresistive layer on the top dielectric layer; and
patterning the magnetoresistive layer to form the magnetoresistor and a patterned magnetoresistive layer, wherein the patterned magnetoresistive layer covers a top surface and a side surface of the conductive cap layer.

21. The manufacturing method according to claim 14, wherein, after forming the magnetoresistor, the method further comprises:
forming a conductive connection line to cover and electrically connect the conductive cap layer and the magnetoresistor.
